(19) United States
(12) Patent Application Publication
(10) Pub. No.: US 2016/0336149 A1
(43) Pub. Date: Nov. 17, 2016

(54) CHAMBER COMPONENT WITH WEAR INDICATOR

(71) Applicant: Applied Materials, Inc., Santa Clara, CA (US)

(72) Inventors: Mats LARSSON, Sunnyvale, CA (US); Wai-Fan YAU, Los Altos, CA (US)

(21) Appl. No.: 14/714,022

(22) Filed: May 15, 2015

(51) Int. Cl. H01J 37/32

(52) U.S. Cl. CPC H01J 37/3288

(57) ABSTRACT

A method and apparatus for monitoring wear of a chamber component is disclosed herein. In one embodiment, a chamber component is provided. The chamber component includes a body including a first material, a second material disposed on the first material, the second material having an exposed surface defining an interior surface of the chamber component, and a wear surface disposed at a wear depth below the exposed surface of the second material, the wear surface comprising a third material having a composition that is different than a composition of the first material and the second material.

### BACKGROUND

1. Field

Embodiments disclosed herein generally relate to a chamber component. More particularly, embodiments disclosed herein relate to a chamber component having a wear indicator that indicates wear, etching, sputtering, blasting or erosion of the chamber component.

2. Description of the Related Art

Semiconductor processing involves a number of different chemical and physical processes enabling minute integrated circuits to be created on a substrate. Layers of materials which make up the integrated circuit are created in chambers using methods such as chemical vapor deposition, physical vapor deposition, epitaxial growth, and the like. Some of the layers of material are patterned using wet or dry etching techniques in a caustic environment where chemicals and/or plasmas are utilized to remove portions of a layer or layers.

While the substrate is purposely introduced into this caustic environment, components in the chamber are also exposed to the same environment, causing the component to wear. These chamber components are often etched or otherwise damaged over time, and require replacement when the wear reaches a critical point. Some chamber components can be protected using plasma resistant surface coatings. However, whether the chamber component is coated or uncoated, it is difficult to ascertain the present amount of wear to the component, and thus the appropriate time for replacement of the component.

Therefore, there is a need for a chamber component that includes a wear indicator.

### SUMMARY

A chamber component having a wear indicator and methods for monitoring wear of a chamber component are disclosed herein.

In one embodiment, a chamber component is provided. The chamber component includes a body including a first material, a second material disposed on the first material, the second material having an exposed surface defining an interior surface of the chamber component, and a wear surface disposed at a wear depth below the exposed surface of the second material, the wear surface comprising a third material having a composition that is different than a composition of the first material and the second material.

In another embodiment, a chamber component is provided. The chamber component includes a body comprising a first material and a second material disposed on the first material, and a wear surface disposed at a wear depth within the second material, the wear surface comprising a plurality of nanoparticles having a composition that is different than a composition of the first material and the second material.

In another embodiment, a plasma processing system is provided. The system includes a chamber component comprising a first material and a second material disposed on the first material, the second material having an exposed surface defining an interior surface of the chamber component, and a wear surface disposed at a wear depth below the exposed surface of the second material, the wear surface comprising a plurality of nanoparticles having a composition that is different than a composition of the first material and the second material.

In another embodiment, a method for monitoring wear of a chamber component is provided. The method includes providing a chamber component to a chamber, the chamber component having a wear indication layer embedded therein, processing a substrate within the chamber with a plasma while monitoring the processing for traces of the wear indication layer, and determining a need to replace the chamber component based on the monitoring.

### BRIEF DESCRIPTION OF THE DRAWINGS

So that the manner in which the above-recited features, advantages and objects of the present invention are attained can be understood in detail, a more particular description of the invention, briefly summarized above, may be had by reference to the embodiments thereof which are illustrated in the appended drawings.

FIG. 1 is a simplified schematic cross-sectional illustration of a process chamber having chamber components utilizing embodiments described herein.

FIG. 2A is an isometric cross-sectional view of a portion of a chamber component according to one embodiment. The chamber component is illustrated with an upper layer removed to show a wear surface.

FIG. 2B is an isometric cross-sectional view of the chamber component of FIG. 2A having an additional layer disposed on the wear surface.

FIG. 3 is an isometric cross-sectional view of a portion of a chamber component according to another embodiment.

FIG. 4 is a cross-sectional view of a portion of a chamber component according to another embodiment.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

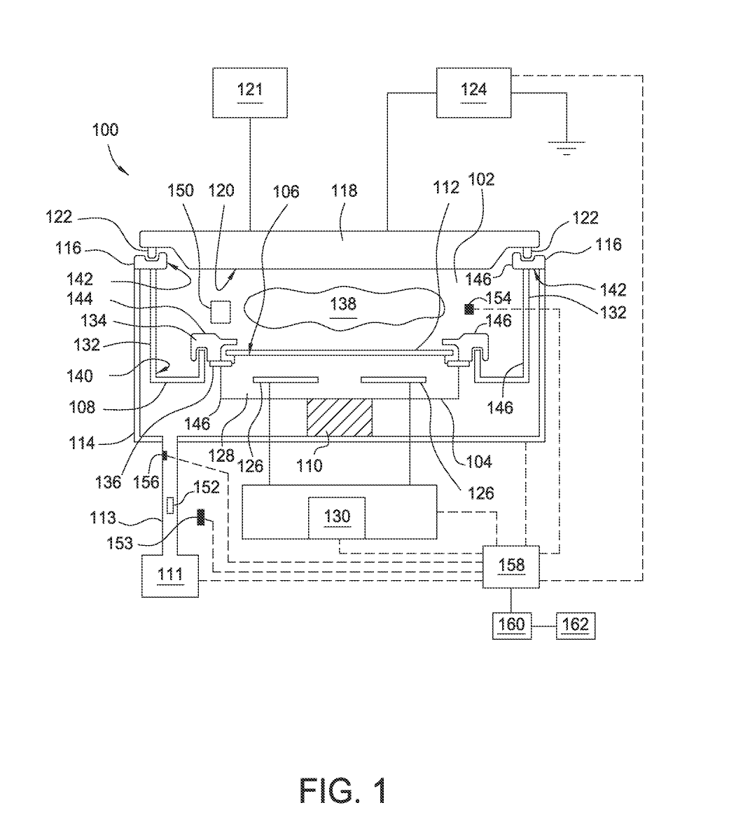

FIG. 1 is a simplified schematic cross-sectional illustration of a process chamber exemplarily illustrated as an etch system 100 having chamber components utilizing embodiments described herein. Other process chambers that may benefit from the disclosure, in which a substrate and chamber components are exposed to a plasma or other corrosive environment, include physical vapor deposition (PVD) chambers and ion metal plasma (IMP) chambers, chemical vapor deposition (CVD) chambers, molecular beam epitaxy (MBE) chambers, atomic layer deposition (ALD) chambers, among others. Similarly, chambers and/or processing systems in which a substrate and chamber components are exposed to wet etchants may also benefit from the disclosure. Other examples of suitable process chambers that may benefit from the disclosure include ion implantation chambers, annealing chambers as well as other furnace chambers that may be cleaned periodically using plasma and/or wet etchants. Process chambers that may benefit from the disclosure may be commercially available from Applied Materials, Inc. of Santa Clara, Calif. Process chambers, as well as chamber components, available from other manufacturers may also benefit from the surface treatment process as described herein.

The etch system 100 comprises a plasma chamber 102 and a substrate support 104 having a support surface 106. The substrate support 104 may be, for example, an electrostatic chuck. The etch system 100 further comprises a shield assembly 108 and a lift system 110. A substrate 112 (e.g., a semiconductor wafer) may be positioned upon the support surface 106 of the substrate support 104 during processing. The plasma chamber 102 is fluidly coupled to a vacuum pump 111 by a foreline 113.

The exemplary plasma chamber 102 includes a cylindrical chamber wall 114 and a support ring 116 which is mounted to the top of the chamber wall 114. The top of the chamber is closed by a gas distribution plate 118 which has an interior surface 120. The gas distribution plate 118 is electrically insulated from the chamber walls 114 by an annular insulator 122 that rests between the gas distribution plate 118 and the support ring 116. Generally, to ensure the integrity of the vacuum pressures in the plasma chamber 102, o-rings (not shown) are used above and below the insulator 122 to provide a vacuum seal. The gas distribution plate 118 may include perforations (not shown) formed therein for distribution of an etchant species therethrough. To facilitate the etching process, a power supply 124 is connected to the gas distribution plate 118. A gas source 121 may also be coupled to the gas distribution plate 118 for supplying etchant gases, cleaning gases and/or an inert gas to the plasma chamber 102. Etchant gases may include halogen containing gases, such as chlorine containing gases, fluorine containing gases, and the like, inert gases may include argon, nitrogen, helium, among others. Other gases in the gas source 121 may include fluorine containing gases utilized for cleaning interior surfaces of the plasma chamber 102.

The substrate support 104 retains and supports the substrate 112 within the plasma chamber 102. The substrate support 104 may contain one or more electrodes 126 imbedded within a support body 128. The electrodes 126 are driven by a voltage from an electrode power supply 130 and, in response to application of the voltage, the substrate 112 may be clamped to the support surface 106 of the substrate support 104 by electrostatic forces. The support body 128 may comprise, for example, a ceramic material.

A wall-like shield member 132 is mounted to the support ring 116. The cylindrical shape of the shield member 132 is illustrative of a shield member that conforms to the shape of the plasma chamber 102 and/or the substrate 112. The shield member 132 may, of course, be of any suitable shape. In addition to the shield member 132, the shield assembly 108 also includes an annular focus ring 134 having an inner diameter which is selected so that the ring fits over a peripheral edge of the substrate 112 without contacting the substrate 112. The focus ring 134 rests upon an alignment ring 136 and the alignment ring 136 is supported by a flange that extends from the substrate support 104.

During an etch process, process gas is supplied to the plasma chamber 102 and power is supplied to gas distribution plate 118. The process gas is ignited into a plasma 138 and is accelerated toward the substrate 112. The etchant species etch the substrate 112 to form features thereon. Excess process gases, as well as material that has been etched, are exhausted from the plasma chamber 102 through the vacuum pump 111. A controller 158 may be utilized to control operations of the plasma chamber 102.

While the shield assembly 108 generally confines the plasma 138 within a reaction zone above the substrate 112, inevitably, the plasma 138 attacks an interior surface 140 of the shield assembly 108, an interior surface 142 of the support ring 116, a surface 144 of the focus ring 134, an interior surface 142 of the gas distribution plate 118, as well as other interior chamber surfaces. Furthermore, other surfaces, such as the support surface 106 of the substrate support 104 may erode due to the plasma 138 during etch sequences and/or cleaning sequences. The rate of erosion or wear on the chamber components is not easily determined and thus, preventative maintenance (PM) may be randomly set or set at predetermined intervals. PM requires breaking vacuum and taking the system off-line. However, the PM may reveal that the chamber components have additional usable life such that the PM was not necessary.

In order to reduce downtime and/or realize actual PM time, one or more of the chamber components include a wear indicator that alerts an operator when the chamber component has reached a usable limit and is in need of replacement. The wear indicator may be integral with the material of the chamber components as well as materials of interior surfaces of the plasma chamber 102.

In general the term “interior surface” refers to any surface that has an interface with the plasma chamber 102. A “chamber component” refers to any detachable element housed completely or partially within the plasma chamber 102. The chamber component may be a plasma chamber component, i.e. a chamber component placed within a plasma chamber, such as, for example, the plasma chamber 102, as well as a component of a wet etch system that is in fluid communication with acids or other etchants. A “chamber component” may also refer to a consumable element within or on a plasma chamber, such as, for example, the plasma chamber 102, which must be replaced after a number of processing and/or cleaning cycles. A “chamber component” may also refer to a consumable element of a wet etch system that is in fluid communication with acids or other etchants.

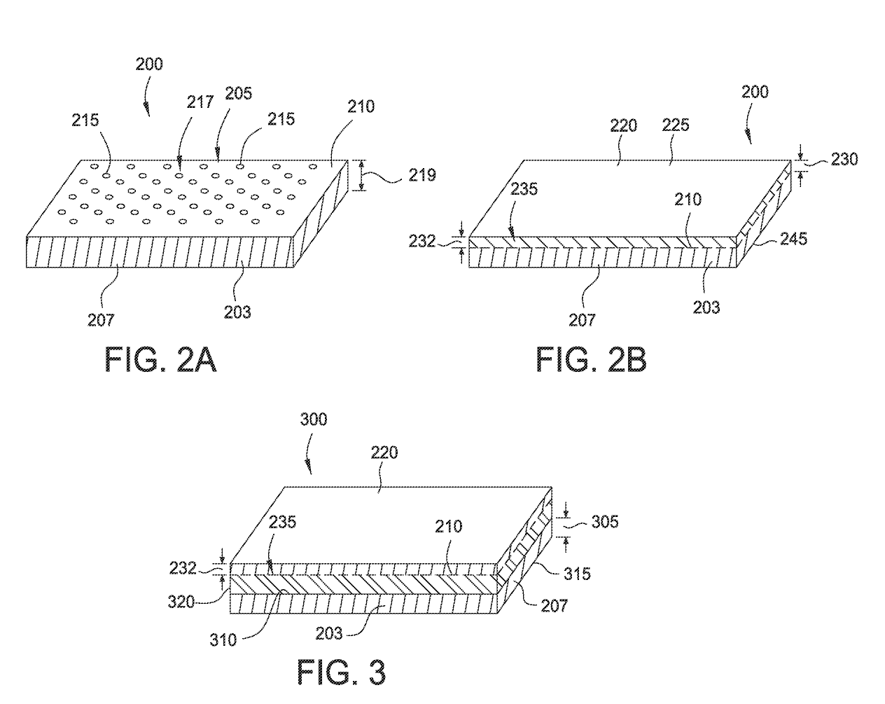

FIG. 2A is an isometric cross-sectional view of a portion of a chamber component 200 according to one embodiment. The chamber component 200 may be, for example, a portion of: the shield assembly 108, the support ring 116, the focus ring 134, the support body 128, the alignment ring 136, the gas distribution plate 118, or the substrate support 104, all shown in FIG. 1. The chamber component 200 may also be a component a wet etch system (not shown) or a component utilized in other environments that erodes a surface of the chamber component 200. An upper layer of the chamber component 200 is not illustrated in order to show a wear surface 205 of the chamber component 200.

The chamber component 200 includes a body 203 having the wear surface 205 that is described in more detail below. The body 203 may comprise a base material or first material 207. The first material 207 may be a metallic material, a ceramic material, a quartz material, or other material suitable for use in an environment that is substantially non-reactive in plasma environments, and/or in the presence of acids or etchants. The first material 207 may be a material that substantially provides a geometric shape and structural integrity of the chamber component 200. Examples of metallic materials include aluminum, stainless steel, titanium, or the like. Examples of ceramic materials include alumina and silicon carbide or other ceramic material. The body 203 also includes a surface 210 having a plurality of nanoparticles 215 disposed thereon.

The nanoparticles 215 may be utilized as a wear indicator 217 and comprise a second material that may be different than the first material 207. In some embodiments, the nanoparticles 215 may comprise materials that are not reactive and/or detrimental to processes performed in the plasma chamber 102 (FIG. 1). In other embodiments, the nanoparticles 215 may be reactive with the processes performed in the plasma chamber 102. In some embodiments, the nanoparticles 215 may include organic nanoparticles. In one embodiment, the nanoparticles 215 may include molecular or elemental rings. Examples of the nanoparticles 215 include allotropes of carbon (C), such as carbon nanotubes and other structures, molecular carbon rings having 5 bonds (pentagonal), 6 bonds (hexagonal), or more than 6 bonds. Other examples of the nanoparticles 215 include fullerene-like supramolecules. In one embodiment, the nanoparticles 215 may be a ceramic material, alumina, glass (e.g., silicon dioxide (SiO₂)), and combinations thereof or derivatives thereof. In another embodiment, the nanoparticles 215 may include metal oxides, such as titanium (IV) oxide or titanium dioxide (TiO₂), zirconium (IV) oxide or zirconium dioxide (ZrO₂), combinations thereof and derivatives thereof, among other oxides. In one embodiment, the thickness of each of the nanoparticles 215 may be on the order of nanometers (e.g., 1 to 100 nanometers). There are many possible nanoparticle compositions that can be potentially used as a wear indicator 207. A long list of nanoparticles 215 and size ranges include, for example Ag, Al, Au, Pt, B, Bi, Co, Cr, Cu, Fe, In, Mo, Mg, Nb, Ni, Si, Sn, S, Ta, Ti, W, Zn, and many more commercially available nanoparticles 215 and compositions (see e.g. http://www.us-nano.com/nanopowders).

The body 203 may have a thickness 219 which includes a partial thickness of the final thickness specification for the particular chamber component 200. The surface 210 where the nanoparticles 215 are provided is intended to be embedded by another material prior to use in the plasma chamber 102 (shown in FIG. 1). Thus, an additional layer or layers of another material is provided over the surface 210. The surface 210 and the nanoparticles 215 are embedded by the additional material at a desired depth described in further detail below.

FIG. 2B is an isometric cross-sectional view of the chamber component 200 of FIG. 2A. A cap layer 220 is shown disposed over the surface 210 and the nanoparticles 215. The cap layer 220 may be the same as the first material 207 or the cap layer 220 may be another material that is different from the first material 207. In some embodiments, the cap layer 220 may be a coating 225. The coating 225 may be a plasma sprayed yttria-containing coating, a zirconia-containing coating, a yttria-zirconia alloy coating, or other ceramic coatings as well as other non-ceramic coatings. The coating 225 may also be applied by an electroplating process. The nanoparticles 215 comprise a material that is different than the material of the cap layer 220, at least in the presence of plasma. For example, the material of the nanoparticles 215 is configured to exhibit detectable properties when in an ionized state, or in a recombined state, that are different than the properties of the cap layer 220 when in an ionized state, or in a recombined state.

A thickness 230 of the coating 225 may be chosen based on the thickness 219 (FIG. 2A) where the nanoparticles 215 are provided. Thus, a wear indication layer 235 comprising the nanoparticles 215 may be formed at a wear depth 232 within the chamber component 200. The wear depth 232 (the level where the wear indication layer 235 may be disposed) may be the same as the thickness 230 of the coating 225. The thickness 230 may be depth within the chamber component 200 that, when exposed, indicates a need to replace the chamber component 200. Exposure of the wear indication layer 235 through the thickness 230 may be used as an indicator that the chamber component 200 is in need of replacement within a specified time period. The specified time period may be within a few hours up to a few days, or within another desired time period.

FIG. 3 is an isometric cross-sectional view of a portion of a chamber component 300 according to another embodiment. The chamber component 300 may be, for example, a portion of: the shield assembly 108, the support ring 116, the focus ring 134, the support body 128, the alignment ring 136, the gas distribution plate 118, or the substrate support 104, all shown in FIG. 1. The chamber component 300 may also be a component a wet etch system (not shown) or a component utilized in other environments that erodes a surface of the chamber component 300.

The chamber component 300 comprises a body 203 made of a base material or first material 207. The first material 207 may be a metallic material, a ceramic material, a quartz material, or other material suitable for use in other environments that erodes a surface of the chamber component 300. Examples of metallic materials include aluminum, stainless steel, titanium, or the like, and may be similar to the chamber component 200 described in FIGS. 2A and 2B. Examples of ceramic materials include silicon carbide or other ceramic material. The first material 207 may have a thickness 305 between a first surface 310 and an opposing second surface 315. In this embodiment, the body 203 of the chamber component 300 comprises a coating layer 320 between the first surface 310 and the cap layer 220. The coating layer 320 may be a coating as described above in reference to the cap layer 220 of FIG. 2B. A wear indication layer 235 is also included between the first surface 310 and the cap layer 220 at a wear depth 232 within the chamber component 300. The wear indication layer 235 includes a plurality of nanoparticles 215 as described herein. The wear depth 232 (the level where the wear indication layer 235 is disposed) may be depth within the chamber component 300 that indicates a need to replace the chamber component 300. In one embodiment, a thickness of the wear indication layer 235 may be about 1 microns (μm) to about 10 μm; however 0.1 μm to about 100 μm is also possible depending on geometric shape of the chamber component. In one embodiment, a thickness of the wear indication layer 235 may be about 0.5% to about 10% relative to a thickness of the cap layer 220 (i.e., the wear depth 232), for example, about 1% to about 5% relative to the wear depth 232.

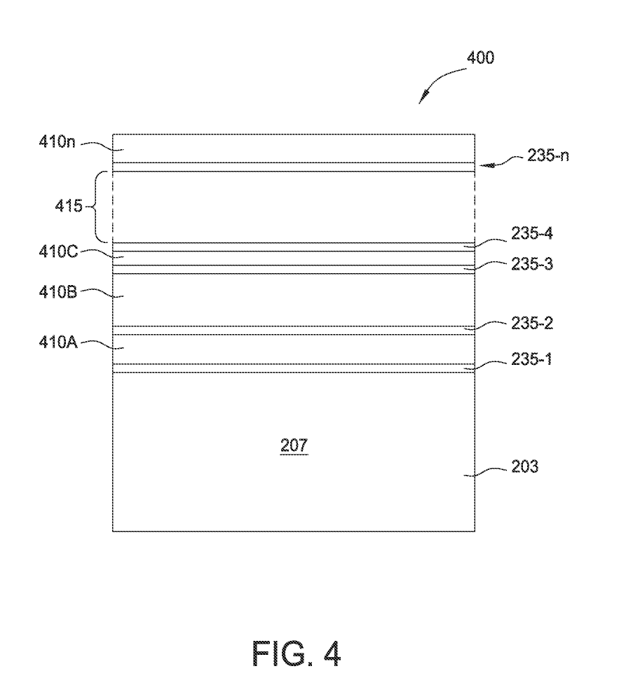

FIG. 4 is a cross-sectional view of a portion of a chamber component 400 according to another embodiment. The chamber component 400 may be, for example, a portion of: the shield assembly 108, the support ring 116, the focus ring 134, the support body 128, the alignment ring 136, the gas distribution plate 118, or the substrate support 104, all shown in FIG. 1. The chamber component 400 may also be a component a wet etch system (not shown) or a component utilized in other environments that erodes a surface of the chamber component 400.

The chamber component 400 comprises a body 203 made of a base material or first material 207. The first material 207 may be a metallic material, a ceramic material, a quartz material, or other material suitable for use in other environments that erodes a surface of the chamber component 400. Examples of metallic materials include aluminum, stainless steel, titanium, or the like, and may be similar to the chamber component 200 described in FIGS. 2A and 2B.

In this embodiment, the chamber component 400 includes a plurality of wear indication layers 235-1, 235-2, 235-3, 235-4 through 235-n. Each of the wear indication layers 235-1 through 235-n may include the nanoparticles 215 as described above. Each of the wear indication layers 235-1 through 235-n may be coated or provided with a cap layer 410A-410n similar to the cap layer 220 described in FIG. 2B and/or the coating layer 320 described in FIG. 3. A region 415 may be a layer or layers of wear indication layers (not shown) alternating with cap layers (not shown).

According to this embodiment, lifetime of the chamber component 400 may be monitored. For example, a first lifetime monitoring event may be provided when the cap layer 410n is eroded to expose the wear indication layer 235-n. A second lifetime monitoring event may be provided when the cap layer 410C is eroded to expose the wear indication layer 235-4. The first or second lifetime monitoring event may indicate moderate use of the chamber component 400 to the operator. The first and second lifetime monitoring event may also be used by an operator to schedule a future PM. Similarly, when other cap layers 410B and/or 410A erode to expose the respective wear indication layers 235-2 and 235-1, other lifetime events may be provided that indicate more urgent replacement times for the chamber component 400. For example, exposure of the wear indication layer 235-2 may indicate that the chamber component 400 should be replaced within a few days to a few weeks. Similarly, exposure of the wear indication layer 235-1 may indicate that the chamber component 400 should be replaced within a few hours to a few days. In addition, trend data relating to the wear of the chamber component 400 may be compiled based on the monitoring events provided by the wear indication layers 235-1 through 235-n.

The wear indication layers 235-1 through 235-n may include the same nanoparticles 215 or different nanoparticles 215. For example, for each chamber component having one or more of the wear indication layers 235-1 through 235-n may include a specific nanoparticle composition that provides a specific metrological signature in each of the wear indication layers 235-1 through 235-n. In one embodiment, Mo, for example, may be utilized as the nanoparticles 215 for each of the wear indication layers 235-1 through 235-n for the chamber component 400. In another embodiment, the wear indication layer 235-n may include Mo nanoparticles, while other wear indication layers 235-1 through 235-4 may include one or more of Mg, Nb, Ni and Tl, respectively, for example. Thus, specific wear indication layers 235-1 through 235-n of the chamber component 400 may be identified by the signature of the nanoparticles 215 in each wear indication layer 235-1 through 235-n.

The thickness and composition of both of the wear indication layers 235-1 through 235-n and cap layers 410A-410n layers can vary between different chamber components. The thickness of the wear indication layers 235-1 through 235-n may vary to some extent depending on the size of the nanoparticles. however generally All cap layers 410A-410n layers might be composed of the same material and may vary significantly in thickness.

The wear indication layer 235 may be formed by various methods. In one example, a chamber component, such as the chamber component 200 described in FIG. 2A, may be placed in a plating solution containing appropriate nanoparticles 215. The body 203 of the chamber component 200 may include a conductive material as the first material 207. The body 203 may be configured as an anode in the plating solution. An electrical bias, such as direct current (DC) power, is applied to the plating solution and the body 203. The nanoparticles 215 in the solution are then plated onto exposed surfaces of the body 203, particularly the wear surface 205, for a specified time period.

The time period may vary based on a desired density or concentration of nanoparticles on the wear surface 205. In the embodiment depicted in FIG. 2A, a density of nanoparticles in relation to a surface area of the wear surface 205, may be between about 1% to about 10%. However, the density may be more or less, depending on user preference. A thickness of a layer or layers of the nanoparticles, at least on the wear surface 205, may be on the order of nanometers and even to picoscale dimensions. In one aspect, density and/or thickness may be determined such that structural integrity of the chamber component 200 is not compromised. However, the density and/or concentration of nanoparticles may increase detectability of the nanoparticle signals.

Alternatively or additionally, the polarity of the plating solution and the body 203 may be reversed such that de-plating from the wear surface 205 occurs. The de-plating time period may be based on a desired density, thickness and/or concentration of nanoparticles on the wear surface 205, as discussed above.

Once a desired density, thickness and/or concentration of nanoparticles are deposited on the wear surface 205, the cap layer 220, as shown in FIG. 2B, may be formed over the wear indication layer 235. Thereafter, the chamber component may be installed in or on a chamber, such as the plasma chamber 102 of FIG. 1. Alternatively, the chamber component may be packaged for later use.

In another example of formation of the wear indication layer 235, a chamber component, such as the chamber component 300 shown in FIG. 3, may be provided with nanoparticles during the manufacturing process of the component. For example, the process of forming the coating layer 320 on the body 203 may be interrupted at a pre-determined depth (i.e. the wear depth 232), and the nanoparticles may be applied to the chamber component 300. The nanoparticles may be applied to at least the exposed surface of the coating layer 320 by a coating process. A desired density, thickness and/or concentration of nanoparticles on the exposed surface of the coating layer 320 may be controlled by the coating process.

In one embodiment, the coating process includes applying a diluted dispersion of colloidal nanoparticles to the exposed coating layer 320. The nanoparticles may be separated in the dispersion by organic ligands that may be attached as surfactants to surfaces of the nanoparticles. Separating the nanoparticles with organic ligands may prevent formation of clusters of nanoparticles on the exposed surface of the coating layer 320. Separating the nanoparticles may also provide a desired spacing between adjacent nanoparticles. The surface of the coating layer 320 having the nanoparticles disposed thereon may then be heated to remove the organic ligands, if desired.

After the coating process is complete, the formation of the coating layer 320 may resume, such as by forming the cap layer 220 to encapsulate the wear indication layer 235. Thereafter, the chamber component may be installed in or on a chamber, such as the plasma chamber 102 of FIG. 1. Alternatively, the chamber component may be packaged for later use.

In another example of formation of the wear indication layers 235-1 through 235-n, a chamber component, such as the chamber component 400 shown in FIG. 4, may be provided with nanoparticles during the manufacturing process of the component. For example, the nanoparticles may be applied to at least the exposed surface of the first material 207 by a coating process as described above. Further, the process of forming the cap layers 410A-410n may be interrupted at pre-determined depths, and the nanoparticles may be applied to the exposed surfaces thereof by a coating process as described above. A desired density, thickness and/or concentration of nanoparticles on the exposed surfaces of the first material 207 and/or the cap layers 410A-410n may be controlled by the coating process as described above. To increase the number of nanolayers used on the chamber component 400 the exposed surfaces can be polished between deposition of subsequent layers so that the surface roughness is kept within specifications. The number of resolvable, i.e. detectable wear indication layers 235-1 through 235-n may be defined by the surface roughness, the thickness of each wear indication layers 235-1 through 235-n and the thickness of each cap layer 410A-410C layer. Thereafter, the chamber component 400 may be installed in or on a chamber, such as the plasma chamber 102 of FIG. 1. Alternatively, the chamber component 400 may be packaged for later use.

During processing, the chamber component 200, 300 or 400 is installed in the plasma chamber 102 of FIG. 1. While installation may be performed using any of the chamber components 200, 300 or 400, the description is limited to the chamber component 200 for brevity. The chamber component 200 may be installed such that the cap layer 220 is exposed to the plasma 138. Referring again to FIG. 1, conditions within the plasma chamber 102 may be monitored through one or more windows 150 and 152 and/or one or more sensors 154 and 156. The windows 150 and/or 152 may be utilized for an optical monitoring system 153. The optical monitoring system 153 may include optical metrology systems such as optical emission spectroscopy, X-ray spectroscopy, or other suitable optical metrology method or device. The sensors 154 and/or 156 may be utilized for mass spectrometry or other suitable spectral metrology method or device. During processing, the cap layer 220 may erode in the presence of plasma 138. The erosion of the cap layer 220 may be monitored optically using the windows 150 and/or 152 and/or chemically utilizing the sensors 154 and/or 156. The composition of the material of the nanoparticles 215, which is different than the composition of the cap layer 220, may be chosen to exhibit a different signal (light and/or electromagnetic energy, or other signal identifiable via detection by the sensors 154 and/or 156), as compared to the composition of the cap layer 220.

As the plasma 138 erodes the cap layer 220 to reach the wear indication layer 235, the nanoparticles 215 may be ionized or otherwise caused to detach from the surface the wear indication layer 235 was deposited onto. The ions of the material of the nanoparticles 215 may then be optically detectable using the windows 150 and/or 152. Alternatively or additionally, the ionized or detached nanoparticles 215 may be chemically detectable utilizing the sensors 154 and/or 156. Detection of the material of the nanoparticles 215 is not limited to ions. Detection of the material of the nanoparticles 215 may be extended to detection of particles in a recombined state.

Additionally, materials for the nanoparticles 215 of discrete chamber components of the chamber may be different in order to identify a specific chamber component optically and/or chemically as discussed above. For example, each chamber component, such as the shield assembly 108, the support ring 116, the focus ring 134, the support body 128, the alignment ring 136, the gas distribution plate 118, or the substrate support 104, all shown in FIG. 1 may each include a wear indication layer 235 having a different composition of nanoparticles 215. Thus, wear of a specific chamber component may be identified utilizing the detection devices or methods described above. There is a great amount of nanoparticles 215 of different elemental composition available, as mentioned above. The different nanoparticles 215 will yield unique elemental composition specific metrological signatures. Hence, by selecting specific and/or unique nanoparticles 215 for each chamber component, the wear of different chamber components can be monitored.

When the nanoparticles 215 are detected at the sensors 154 and/or 156, a signal may be sent to the controller 158. Likewise, when the nanoparticles are detected with the optical monitoring system 153 monitoring the process via the windows 150 and/or 152, a signal may be sent to the controller 158. An alarm, visible or audible, may be provided to a user interface 160 alerting an operator of the wear of the chamber component. The user interface 160 may be a personal computer, a monitor, or other electronic device utilized in industrial settings. The chamber component may also be identified to the operator based on the signal detected. The alarm may be a message to the operator indicating the part, the part, number, and the time period for replacement of the chamber component. For example, the operator may see a message that a specific chamber component needs to be replaced in one hour, 5 hours, 24 hours, 48 hours, depending on the depth of the wear indication layer 235 in the chamber component. Identifying information for the chamber component may assist the operator in ordering a new chamber component.

Alternatively or additionally, an alert may be sent via an internet connection 162 to a parts supplier. The parts supplier may then procure a new chamber component for the operator to replace the specific chamber component. Depending on the time period for replacement, the parts supplier may ship the new chamber component accordingly, or arrange a quick delivery of the new chamber component to the operator. Additionally, the same type of chamber component can, for example, be traced differently for different customers and/or chambers based on the nanoparticle composition. Further, the type of nanoparticle(s) of the chamber component may be varied from time to time in order to prevent non-authentic chamber components from being used and/or monitored in the chamber.

In some embodiments, a plasma processing system is provided. The plasma processing system includes a chamber component comprising a first material and a second material disposed on the first material. The second material has a surface defining an interior surface of the chamber component. The chamber component also includes a wear surface disposed at a wear depth below the exposed surface of the second material. The wear surface includes a plurality of nanoparticles having a composition that is different than a composition of the first material and the second material. The chamber component described above may include a gas distribution plate, a support ring, a focus ring, a support body, an alignment ring, or a substrate support. The chamber component described above may include nanoparticles that are distinct for each of the gas distribution plate, the support ring, the focus ring, the support body, the alignment ring, or the substrate support.

In some embodiments, a method for monitoring wear of a chamber component is provided. The method includes providing a chamber component to a chamber, the chamber component having a wear indication layer embedded therein. The method includes processing a substrate within the chamber with a plasma while monitoring the processing for traces of the wear indication layer. The method includes determining that the chamber component needs to be replaced based on the monitoring. The method includes monitoring that may include optically monitoring the plasma or an exhaust from the chamber. The method includes monitoring that may include chemically monitoring the plasma or an exhaust from the chamber. The method may further include providing an alert indicating a need to replace the chamber component. The method may further include communicating the alert to a parts supplier.

While the foregoing is directed to embodiments of the present disclosure, other and further embodiments of the disclosure thus may be devised without departing from the basic scope thereof, and the scope thereof is determined by the claims that follow.

1. A chamber component, comprising:
a body comprising a first material;
a second material disposed on the first material, the second material having an exposed surface defining an interior surface of the chamber component; and
a wear surface disposed at a wear depth below the exposed surface of the second material, the wear surface comprising a third material having a composition that is different than a composition of the first material and the second material.

2. The component of claim 1, wherein the body comprises a component of a plasma chamber.

3. The component of claim 2, wherein the third material comprises a plurality of nanoparticles detectable to provide a positive optical and/or chemical identification of the component.

4. The component of claim 1, wherein the wear surface is disposed within the second material.

5. The component of claim 1, wherein the third material comprises nanoparticles.

6. The component of claim 5, wherein the nanoparticles are dispersed on about 1 percent to about 10 percent of the wear surface.

7. The component of claim 5, wherein the nanoparticles comprise an inorganic material.

8. The component of claim 1, wherein the first material and the second material are the same.

9. The component of claim 1, wherein the first material and the second material are different.

10. The component of claim 1, further comprising:
a plurality of wear surfaces disposed at a respective wear depth below surfaces of the second material, wherein each of the wear surfaces comprise the third material.

11. The component of claim 10, wherein the third material comprises a nanoparticle layer.

12. The component of claim 11, wherein the nanoparticle layer for each of the wear surfaces is the same.

13. The component of claim 11, wherein the nanoparticle layer for each of the wear surfaces is different.

14. A chamber component, comprising:
a body comprising a first material and a second material disposed on the first material; and
a wear surface disposed at a wear depth within the second material, the wear surface comprising a plurality of nanoparticles having a composition that is different than a composition of the first material and the second material.

15. The component of claim 14, wherein the body comprises a gas distribution plate, a support ring, a focus ring, a support body, an alignment ring, or a substrate support.

16. The component of claim 14, wherein the composition of the nanoparticles are detectable to provide a positive optical and/or chemical identification of the component.

17. The component of claim 14, wherein the first material and the second material are different.

18. The component of claim 14, wherein the nanoparticles are dispersed on about 1 percent to about 10 percent of the wear surface.

19. The component of claim 14, wherein the nanoparticles comprise an inorganic material.

20. A plasma processing system, comprising:
a chamber component comprising a first material and a second material disposed on the first material, the second material having an exposed surface defining an interior surface of the chamber component; and
a wear surface disposed at a wear depth below the exposed surface of the second material, the wear surface comprising a plurality of nanoparticles having a composition that is different than a composition of the first material and the second material.
